(19) United States
(12) Patent Application Publication
(10) Pub. No.: US 2026/0140285 A1
(43) Pub. Date: May 21, 2026

(54) LENS AND LIGHT-EMITTING MODULE

(71) Applicant: NICHIA CORPORATION, Anan-shi (JP)

(72) Inventor: Tetsuya TOMINAGA, Komatsushima-shi (JP)

(73) Assignee: NICHIA CORPORATION, Anan-shi (JP)

(21) Appl. No.: 19/391,088

(22) Filed: Nov. 17, 2025

(30) Foreign Application Priority Data
Nov. 21, 2024 (JP) 2024-203436

(51) Int. Cl. G02B 3/08; H10H 29/24; H10H 29/855

(52) U.S. Cl. CPC G02B 3/08; H10H 29/24; H10H 29/855

(57) ABSTRACT

A lens includes: a first light-transmissive portion including a light incident surface and a light exiting surface located at a side opposite to the light incident surface. The first light-transmissive portion has a through hole extending from the light incident surface to the light exiting surface. At least one of the light incident surface or the light exiting surface includes: an annular convex surface or an annular concave surface, and at least one annular protrusion surrounding the through hole in a top view.

### CROSS REFERENCE TO RELATED APPLICATION

This application claims priority to Japanese Patent Applications No. 2024-203436, filed on Nov. 21, 2024, the entire contents of which are hereby incorporated by reference.

### BACKGROUND

### Technical Field

The present disclosure relates to a lens and a light-emitting module.

### Background Art

Light-emitting modules including semiconductor elements such as light-emitting diodes (LEDs) have been widely used. As a lens used in such a light-emitting module, for example, Japanese Patent Publication No. 2018-142506 discloses a lens structure in which a through hole that extends along an optical axis of a convex lens is provided.

### SUMMARY

One object of an embodiment according to the present disclosure is to provide a lens and a light-emitting module with which light distribution control can be performed.

A lens according to an embodiment of the present disclosure includes a first light-transmissive portion including a light incident surface and a light exiting surface located at a side opposite to the light incident surface. The first light-transmissive portion has a through hole extending from the light incident surface to the light exiting surface. At least one of the light incident surface or the light exiting surface includes an annular convex surface or an annular concave surface, and at least one annular protrusion surrounding the through hole in a top view.

A light-emitting module according to an embodiment of the present disclosure includes a light source including a first light-emitting unit located in a central region of the light source in a top view and a second light-emitting unit located in an outer peripheral region located on an outer periphery of the central region in a top view, the first light-emitting unit and the second light-emitting unit being configured to be individually driven; and the lens according to any one of claims 1 to 6, the lens being disposed above the light source. The light source is disposed such that the first light-emitting unit overlaps the through hole in a top view. Light emitted from the first light-emitting unit is irradiated through the through hole at a first full width at half maximum angle, and light emitted from the second light-emitting unit is irradiated through the annular protrusion at a second full width at half maximum angle. The first full width at half maximum angle is smaller than the second full width at half maximum angle.

According to an embodiment of the present disclosure, the lens and the light-emitting module with which light distribution control can be performed are provided.

### BRIEF DESCRIPTION OF DRAWINGS

FIG. 1 is a schematic top view of a light-emitting module including a lens according to a first embodiment.

FIG. 2 is a schematic cross-sectional view taken along line II-II in FIG. 1.

FIG. 3 is a schematic diagram illustrating behavior of light emitted from the light-emitting module including the lens according to the first embodiment.

FIG. 4 is a schematic top view illustrating a configuration of a light source included in the light-emitting module including the lens according to the first embodiment.

FIG. 5 is a schematic cross-sectional view taken along line V-V in FIG. 4.

FIG. 6 is a schematic top view of the light-emitting module according to a modified example of the first embodiment.

FIG. 7 is a schematic cross-sectional view taken along line VII-VII in FIG. 6.

FIG. 8 is a schematic top view of a light-emitting module including a lens according to a second embodiment.

FIG. 9 is a schematic cross-sectional view taken along line IX-IX in FIG. 8 and illustrating behavior of light exiting from the lens according to the second embodiment.

FIG. 10 is a schematic top view of a light-emitting module including a lens according to a third embodiment.

FIG. 11 is a schematic cross-sectional view taken along line XI-XI in FIG. 10 and illustrating behavior of light exiting from the lens according to the third embodiment.

FIG. 12 is a schematic diagram illustrating an irradiation angle of light emitted from the light source.

### DETAILED DESCRIPTION

Lenses and light-emitting modules according to embodiments of the present disclosure will be described in detail with reference to the accompanying drawings.

However, the following embodiments are examples of lenses and light-emitting modules to embody the technical concept of the present embodiment, and the present embodiment is not limited to the embodiments described below. The dimensions, materials, shapes, relative arrangements, and the like of components described in the embodiments are not intended to limit the scope of the present disclosure, but are merely illustrative examples, unless otherwise specifically stated. Note that the sizes, positional relationship, or the like of members illustrated in the drawings may be exaggerated for clarity of description. In the following description, members having the same terms and reference characters represent the same members or members of the same quality, and a detailed description of these members is omitted as appropriate. As a cross-sectional view, an end view illustrating only a cut surface may be used.

In the drawings, directions may be indicated by an X-axis, a Y-axis, and a Z-axis corresponding to directions orthogonal to each other. An X direction along the X-axis and a Y direction along the Y-axis indicate directions along a light-emitting surface of a light-emitting unit included in the light-emitting module according to the embodiment. AZ direction along the Z-axis indicates a direction orthogonal to the light-emitting surface. In other words, the light-emitting surface of the light-emitting unit is parallel to an XY plane, and the Z-axis is orthogonal to the XY plane.

The direction the arrow points to in the X direction is the +X side, and a side opposite to the +X side is the −X side, and the direction the arrow points to in the Y direction is the +Y side, and a side opposite to the +Y side is the −Y side. The direction the arrow points to in the Z direction is the +Z side, and a side opposite to the +Z side is the −Z side. In the embodiments, the light-emitting unit included in the light-emitting module emits light toward the +Z side as an example. However, these matters do not limit orientations of the lenses and the light-emitting modules according to the embodiments when the lenses and the light-emitting modules are used, and the lenses and the light-emitting modules according to the embodiments may be oriented in any appropriate direction.

In the present specification, a surface of an object when viewed from the +Z side is referred to as an “upper surface,” and a surface of the object when viewed from the −Z side is referred to as a “lower surface.” In addition, the +Z side when viewed from the object may be referred to as an “upper side,” and the −Z side when viewed from the object may be referred to as a “lower side.” In the following embodiments, “being aligned with the X-axis, the Y-axis, or the Z-axis” includes the case in which an object has an inclination within a range of +10° relative to the corresponding axis. In the present embodiment, the orthogonality may include an error within +10° with respect to 90°. In the present specification, “along” may include an error within +10° with respect to 0°. Furthermore, “disposing” includes not only a case of disposing two objects in direct contact with each other but also includes a case of indirectly disposing, for example, disposing one object and the other object with another member provided therebetween. The “thickness” indicates a length of the target object in the Z direction.

In the present specification or the claims, when a plurality of constituent components are provided and these constituent components are to be denoted individually, the constituent components may be distinguished by adding terms such as “first,” “second,” and the like in front of the terms of the constituent components. Objects to be distinguished may differ between the present specification and the claims.

### First Embodiment

Configuration of Light-Emitting Module Including Lens According to First Embodiment

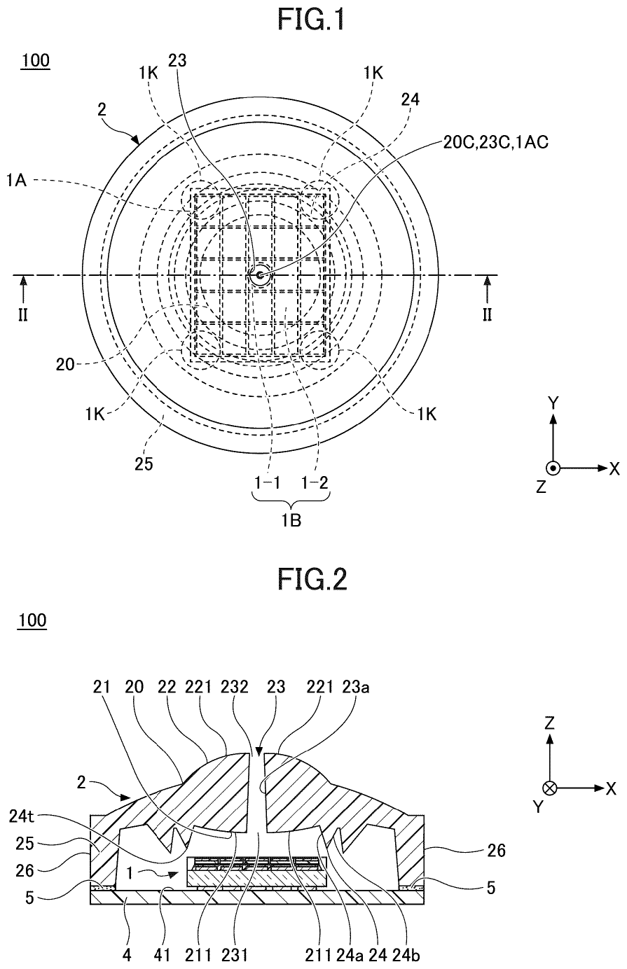

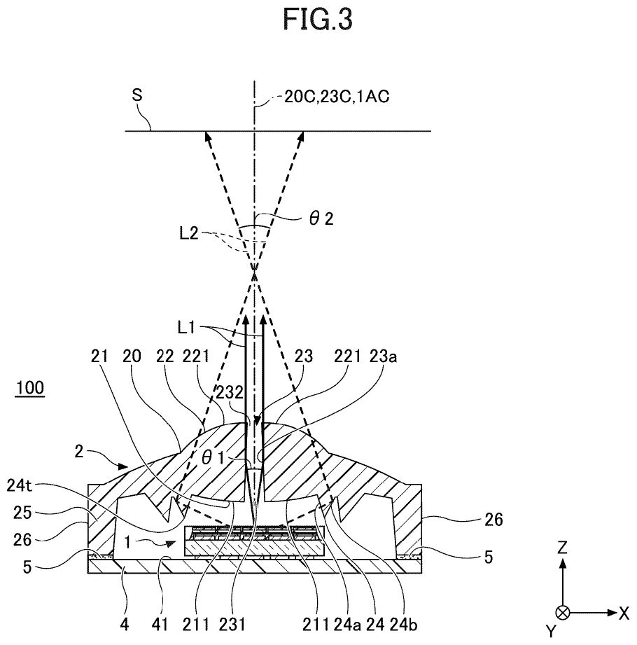

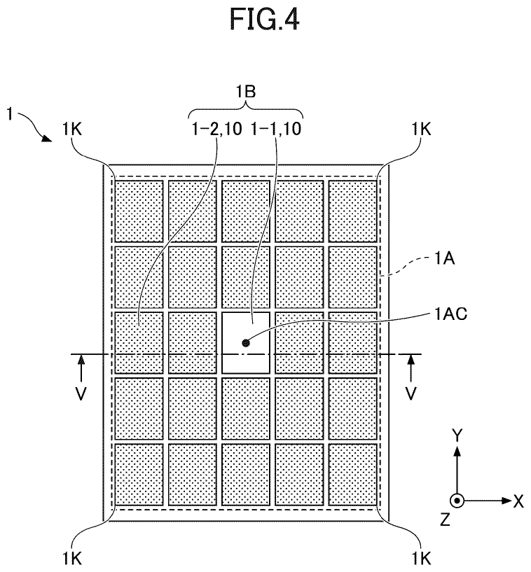

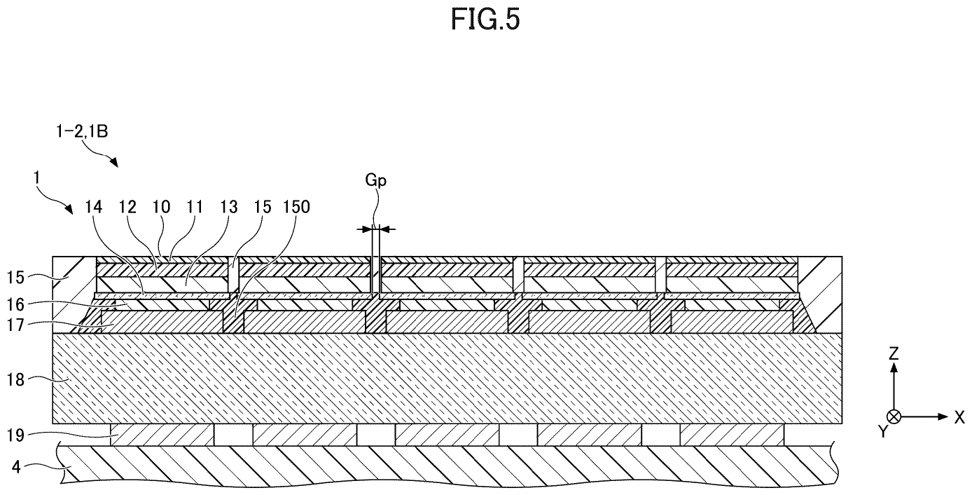

A configuration of a light-emitting module including a lens according to a first embodiment will be described with reference to FIGS. 1 to 5. FIG. 1 is a schematic top view of a light-emitting module 100 including a lens 2 according to the first embodiment. FIG. 2 is a schematic cross-sectional view taken along line II-II in FIG. 1. FIG. 3 is a schematic cross-sectional view illustrating behavior of light emitted from the light-emitting module 100 including the lens 2 according to the first embodiment. FIG. 4 is a schematic top view illustrating a configuration of a light source 1 included in the light-emitting module 100 including the lens 2 according to the first embodiment. FIG. 5 is a schematic cross-sectional view taken along line V-V in FIG. 4.

The light-emitting module 100 is, as an example, a light-emitting module used in a light source of a camera flash of an imaging device mounted in a smartphone, or in a flashlight function and the like of a smartphone. Examples of the imaging device include a camera for capturing a still image, a video camera for capturing a moving image, and the like.

As illustrated in FIGS. 1 and 2, the light-emitting module 100 includes the light source 1 and the lens 2 disposed above the light source 1.

In addition, in the example illustrated in FIGS. 1 and 2, the light-emitting module 100 further includes a substrate 4 on which the light source 1 and the lens 2 are disposed, and an adhesive member 5. The lens 2 is bonded to an upper surface 41 of the substrate 4 by the adhesive member 5.

In the example illustrated in FIG. 1, an outer shape of the light-emitting module 100 is substantially circular in a top view. In a top view, an outer shape of the lens 2 is the outer shape of the light-emitting module 100. In the example illustrated in FIG. 1, the outer shape of the lens 2 is substantially circular in a top view. However, the outer shapes of the light-emitting module 100 and the outer shape of the lens 2 are not limited to substantially circular shapes in a top view and may have other shapes such as substantially elliptical shapes, substantially rectangular shapes, or substantially polygonal shapes.

The light source 1 is mounted on the upper surface 41 of the substrate 4. In the examples illustrated in FIGS. 1 and 4, the light source 1 has a substantially rectangular outer shape in a top view. The light source 1 includes a plurality of light-emitting units. The light source 1 includes 25 light-emitting units 1B each having a substantially rectangular light-emitting surface 10. The 25 light-emitting units 1B are disposed in a matrix of 5 rows and 5 columns. The light-emitting surface 10 refers to a main light extraction surface of the light-emitting unit 1B. Therefore, the light-emitting surface 10 of the light-emitting unit 1B also serves as a light-emitting surface of the light source 1. A region including the light-emitting surface 10 corresponds to a light-emitting region 1A. When the light source 1 includes a plurality of the light-emitting surfaces 10, the light-emitting region 1A is a region formed by connecting outer edges of outermost ones of the light-emitting surfaces 10 in a top view. In the example illustrated in FIG. 4, the light-emitting region 1A includes the 25 light-emitting surfaces 10. The shape of the outer edge of the light-emitting region 1A is a substantially rectangular shape in a top view and includes four corner portions 1K. The number of the light-emitting units 1B included in the light source 1 is not limited to 25, and may be any number equal to or greater than two. The light source 1 is not limited to a rectangular shape in a top view and may have another shape such as a substantially circular shape, a substantially elliptical shape, or a substantially polygonal shape.

The light source 1 includes a first light-emitting unit 1-1 located in a central region thereof and a second light-emitting unit 1-2 located in an outer peripheral region located on an outer periphery of the central region in a top view. In the example illustrated in FIG. 1, the light source 1 has 25 light-emitting units 1B, and specifically, includes one first light-emitting unit 1-1 and the 24 second light-emitting units 1-2 disposed in the outer peripheral region so as to surround the entire periphery of the first light-emitting unit 1-1. The central region is a region overlapping a center 1AC of the light-emitting region 1A in a top view. In the central region, a plurality of the first light-emitting units 1-1 may be arranged, and the plurality of first light-emitting units 1-1 may be arranged in a matrix.

As illustrated in FIG. 2, in the present embodiment, the lens 2 includes a first light-transmissive portion 20 including a light incident surface 21 and a light exiting surface 22 located at a side opposite to the light incident surface 21. In the example illustrated in FIG. 2, the lens 2 includes a first support portion 25 that supports the first light-transmissive portion 20. The first support portion 25 is bonded to the upper surface 41 of the substrate 4 by the adhesive member 5. In the present embodiment, the center 1AC of the light-emitting region 1A overlaps the central axis 20C of the first light-transmissive portion 20 in a top view. The light source 1 emits light from the light-emitting surface 10 included in each of the plurality of light-emitting units 1B in a direction toward the first light-transmissive portion 20. The first light-transmissive portion 20 has a through hole 23 that is continuous with the light incident surface 21 and the light exiting surface 22. In the example illustrated in FIGS. 1 and 2, the light incident surface 21 includes two annular protrusions 24 disposed to surround the through hole 23 in a top view. The annular protrusion 24 has a circular annular shape centered on the central axis 20C of the first light-transmissive portion 20, and the two annular protrusions 24 are arranged concentrically. Note that, the annular protrusion 24 disposed so as to surround the through hole 23 in a top view may be provided on the light exiting surface 22. Further, the annular protrusion 24 may be provided at both the light incident surface 21 and the light exiting surface 22. Any appropriate number of the annular protrusions 24 may be provided, as long as at least one annular protrusion 24 is provided. In FIGS. 1 to 3, the central axis 20C of the first light-transmissive portion 20, a central axis 23C of the through hole 23, and the center 1AC of the light-emitting region 1A of the light source 1 overlap one another. Accordingly, reference characters of the central axis 20C, the central axis 23C, and the center 1AC are indicated together. Also, in the drawings, reference characters may be indicated together for the same purpose.

As illustrated in FIG. 2, the light incident surface 21 includes an annular convex surface 211 surrounding the through hole 23 in a top view. The light exiting surface 22 includes an annular convex surface 221 surrounding the through hole 23 in a top view. The annular protrusion 24 is located at the light incident surface 21 and surrounds the annular convex surface 211 in a top view. The annular protrusion 24 includes an inner lateral surface 24a and an outer lateral surface 24b, at least one of which can refract or reflect light. As illustrated in FIG. 1, the annular protrusion 24 overlaps the corner portion 1K of the light-emitting region 1A of the light source 1.

In the example illustrated in FIG. 2, the through hole 23 includes a first opening 231 located at the light incident surface 21 and a second opening 232 located at the light exiting surface 22. In a direction along the central axis 23C of the through hole 23 that passes through a center 231C of the first opening 231 and a center 232C of the second opening 232, for example, in a Z direction, the first opening 231 is located between the annular protrusion 24 and the second opening 232. For example, the first opening 231 is located between a top portion 24t of the annular protrusion 24 and the second opening 232. When there are a plurality of annular protrusions 24, the first opening 231 is located between the second opening 232 and the top portion 24t of the protrusion 24 closest to the through hole 23 among the plurality of annular protrusions 24.

The first light-emitting unit 1-1 and the second light-emitting unit 1-2 are individually drivable. In addition, the 24 second light-emitting units 1-2 include a plurality of light-emitting units that are individually drivable. That is, the light source 1 may be configured to drive the plurality of second light-emitting units 1-2 individually or in groups. In a case in which the light source 1 includes a plurality of first light-emitting units 1-1, the plurality of first light-emitting units 1-1 may be driven individually or in groups. The one first light-emitting unit 1-1 and the 24 second light-emitting units 1-2 each emit light toward the lens 2 provided above the light source 1.

By controlling a distribution of currents supplied to the first light-emitting unit 1-1 and each of the 24 second light-emitting units 1-2, light distribution of light emitted from the light-emitting module 100 can be controlled.

The light-emitting module 100 can increase contrast of irradiation light on an irradiation surface S irradiated with light from the light source 1 by individually lighting the first light-emitting unit 1-1 and 24 second light-emitting units 1-2 at desired brightness levels, or by lighting the first light-emitting unit 1-1 and the 24 second light-emitting units 1-2 in groups. Further, the light-emitting module 100 can partially irradiate the irradiation surface S by individually turning on the first light-emitting unit 1-1 and the 24 second light-emitting units 1-2, or by turning on the first light-emitting unit 1-1 and the 24 second light-emitting units 1-2 in groups. As used herein, the “partial irradiation” refers to irradiation onto a partial region in the irradiation surface S with light.

In a case in which the light-emitting module 100 is used as a flash light source of an imaging device, for example, light to be emitted from the light-emitting module 100 can be switched between a wide-angle mode and a narrow-angle mode. The wide-angle mode is a mode in which only some of the 24 second light-emitting units 1-2 are caused to emit light, a mode in which all of the 24 second light-emitting units 1-2 are caused to emit light, or a mode in which all of the 24 second light-emitting units 1-2 and the first light-emitting unit 1-1 are caused to emit light. In the wide-angle mode, light emitted from the light-emitting module 100 exhibits a wide-angle light distribution. In addition, the light-emitting module 100 can emit the wide-angle light distribution and an ultra-wide-angle light distribution that is a light distribution wider than the wide-angle light distribution by adjusting the intensity of light of each of the first light-emitting unit 1-1 and the second light-emitting unit 1-2. In the following description, the wide-angle light distribution and the ultra-wide-angle light distribution may be collectively referred to as the wide-angle light distribution or the wide-angle mode. The narrow-angle mode is a mode in which some of the 24 second light-emitting units 1-2 and the first light-emitting unit 1-1 are caused to emit light, or a mode in which only the first light-emitting unit 1-1 is caused to emit light and the second light-emitting units 1-2 are not caused to emit light. In the narrow-angle mode, the light emitted from the light-emitting module 100 exhibits a narrow-angle light distribution. That is, the light distribution angle in the narrow-angle mode is smaller than that in the wide-angle mode.

When the light-emitting module 100 can switch irradiation light in accordance with the wide-angle mode and the narrow-angle mode, for example, shooting in accordance with a shooting mode such as close-up or distant view can be performed by using light emitted from the light-emitting module 100 with an imaging device. In addition, in the case in which the light-emitting module 100 is used as a light source for a flashlight of a smartphone, the light emitted from the light-emitting module 100 is set to a narrow-angle mode, so that the irradiation light can reach a long distance, and the performance of the flashlight can be enhanced.

In the present embodiment, the first light-transmissive portion 20 of the lens 2 is provided with the through hole 23. The light incident surface 21 includes the plurality of annular protrusions 24 disposed so as to surround the through hole 23 in a top view. With this configuration, the light distribution of the light emitted from the light source 1 can be different between the light passing through the through hole 23 and the light passing through the portion of the first light-transmissive portion 20 other than the through hole 23. In the present embodiment, with the difference between light distribution of light passing through the through hole 23 and that of light passing through the portion other than the through hole 23, the lens 2 that can perform light distribution control can be provided. In addition, the present embodiment can provide the light-emitting module 100 that includes the lens 2 and enables light distribution control.

In the lens 2 and the light-emitting module 100, by narrow-angle mode light being irradiated through the through hole 23, the illuminance of light in the narrow-angle mode light becomes higher as compared with a case in which light is irradiated from the light-emitting module having no through hole 23. In addition, in the present embodiment, by wide-angle mode light being irradiated through the annular protrusion 24, light having a wider wide-angle light distribution can be irradiated as compared with a case in which light is irradiated from the light-emitting module having no annular protrusion.

The light incident surface 21 includes the annular convex surface 211, and the light exiting surface 22 includes the annular convex surface 221. The annular protrusion 24 is located on the light incident surface 21 and surrounds the annular convex surface 211 in a top view. The annular protrusion 24 includes the inner lateral surface 24a and the outer lateral surface 24b. The annular protrusion 24 has at least one of the inner lateral surface 24a and the outer lateral surface 24b that can refract or reflect light. The annular protrusion 24 is disposed at a position closer to the second light-emitting unit 1-2 than to the first light-emitting unit 1-1. With this configuration, the light emitted from the second light-emitting unit 1-2 is refracted or reflected by the annular protrusion 24, and thus the utilization efficiency of the light emitted from the second light-emitting unit 1-2 located in the outer peripheral region of the light source 1 is increased. Therefore, in the light distribution control, the light utilization efficiency mainly in the wide-angle mode is increased.

The through hole 23 includes the first opening 231 and the second opening 232, and the first opening 231 is located between the annular protrusion 24 and the second opening 232 in the direction along the central axis 23C of the through hole 23. Thus, the annular protrusion 24 and the light incident surface 21 (annular convex surface 211) can form a recessed portion. By disposing the light-emitting region 1A of the light source 1 inside the recessed portion, the distance between the first light-emitting unit 1-1 and the first opening 231 can be reduced, and therefore, the light emitted by the first light-emitting unit 1-1 can easily pass through the through hole 23, and the light refracted or reflected by the annular protrusion 24 among the light emitted by the first light-emitting unit 1-1 is reduced. As a result, the illuminance of the narrow-angle mode light increases.

As illustrated in FIG. 1, the light source 1 is disposed such that the first light-emitting unit 1-1 overlaps the through hole 23 in a top view. In FIG. 3, among light L1 emitted from the first light-emitting unit 1-1, light beams corresponding to an angle at which the illuminance on the irradiation surface S becomes a half value are indicated by solid line arrows. Among light L2 emitted from the second light-emitting unit 1-2, light beams corresponding to an angle at which the illuminance on the irradiation surface S becomes a half value are indicated by broken line arrows. As illustrated in FIG. 3, the light L1 emitted from the first light-emitting unit 1-1 is irradiated through the through hole 23 at a first full width at half maximum angle θ1. The light L2 emitted from the second light-emitting unit 1-2 is irradiated through the annular protrusion 24 at a second full width at half maximum angle θ2. The first full width at half maximum angle θ1 is smaller than the second full width at half maximum angle θ2. This allows the light distribution of the light L1 and the light distribution of the light L2 to be different from each other, and thus allows for providing the light-emitting module 100 in which the light distribution control can be performed.

As illustrated in FIG. 3, of the light L2 emitted from the second light-emitting unit 1-2, the light L2 irradiated through the annular protrusion 24 travels in a direction toward the central axis 20C of the first light-transmissive portion 20 and is irradiated onto the irradiation surface S. The plurality of light beams included in the light L2 travel in the direction toward the central axis 20C of the first light-transmissive portion 20 and intersect each other on the central axis 20C. Accordingly, the light distribution angle of the light L2 irradiated through an annular protrusion 24 can be controlled so as to become larger. Note that the phrase “intersect each other on the central axis 20C” encompasses not only a case of strictly intersecting each other but also a case in which there is a deviation that may occur in the manufacturing process.

The second light-emitting unit 1-2 includes a plurality of light-emitting units that are individually drivable. By causing the plurality of light-emitting units to individually emit light, the degree of freedom of light distribution control including the wide-angle mode and the narrow-angle mode is increased.

In a top view, the light incident surface 21 and the light exiting surface 22 include an annular convex surface 211 and an annular convex surface 221 surrounding the through hole 23, respectively. The annular protrusion 24 surrounds the annular convex surface 211 and is located on the light incident surface 21. The corner portion 1K of the rectangular light-emitting region 1A overlaps the annular protrusion 24. In order to cause light emitted from the light-emitting module 100 to be in the wide-angle light distribution, when the annular protrusion 24 (particularly, a top portion 24t of the annular protrusion 24) is located in the vicinity of an outer edge of the light-emitting region 1A and the outer lateral surface 24b is located outward the corner portion 1K of the light-emitting region 1A, efficiency of receiving light emitted from the light source 1 by the annular protrusion 24 can be increased.

Each component of the light-emitting module 100 will be described in detail below.

### Light Source 1

The light source 1 will be described with reference to FIGS. 4 and 5. The light source 1 of the present embodiment includes the light-emitting unit 1B including the first light-emitting unit 1-1 and the second light-emitting unit 1-2, and a base body 18. The base body 18 includes a first wiring member 17 on an upper surface thereof and a second wiring member 19 on a lower surface thereof. The light source 1 includes one first light-emitting unit 1-1 and the 24 second light-emitting units 1-2. The first light-emitting unit 1-1 is disposed in a central region of the light source 1 in a top view. The second light-emitting units 1-2 are disposed vertically, horizontally, or in a matrix in a top view. Note that in FIG. 4, in order to distinguish the one first light-emitting unit 1-1 and 24 second light-emitting units 1-2, the first light-emitting unit 1-1 is represented by white, and the second light-emitting units 1-2 are represented by dot hatching. In addition, in FIG. 4, in order to avoid making the drawing complicated, only the second light-emitting unit 1-2 disposed in the first column of the third row among 24 second light-emitting units 1-2 is denoted by a reference sign.

The light source 1 includes, on an upper surface thereof, the light-emitting surface 10 of the light-emitting unit 1B, and is disposed on a +Z side surface of the substrate 4 with a surface opposite to the light-emitting surface 10 serving as a mounting surface. The one first light-emitting unit 1-1 and the 24 second light-emitting units 1-2 each have substantially the same configuration. Therefore, the configuration of the second light-emitting unit 1-2 disposed in the first column of the third row may be described below as a representative example.

In the example illustrated in FIG. 5, the second light-emitting unit 1-2 includes a light-emitting element 14, a wavelength conversion member 13 disposed above the light-emitting element 14, a light diffusion member 12 disposed above the wavelength conversion member 13, and a first covering member 11 disposed above the light diffusion member 12. Further, the second light-emitting unit 1-2 includes a second covering member 15 covering the lateral surfaces of each of the first covering member 11, the light diffusion member 12, the wavelength conversion member 13, and the light-emitting element 14.

The light-emitting element 14 includes, on a surface opposite to the light-emitting surface 10, that is, on a lower surface, at least a pair of positive and negative electrodes 16. The light-emitting element 14 is disposed on the base body 18 with the electrode 16 and the first wiring member 17 interposed therebetween. The lateral surfaces of each of the electrode 16 and the first wiring member 17 and the lower surface of the light-emitting element 14 are covered with a resin member 150. The resin member 150 absorbs an external force applied to the light-emitting element 14 from the outside in the manufacturing process, and reduces the external force applied to the light-emitting element 14.

The base body 18 includes wiring on the surface or both on the surface and in the interior. The first wiring member 17 and the second wiring member 19 are wirings of the base body 18. The light source 1 and the substrate 4 are electrically connected by connecting the electrode 16 of the light-emitting element and the wiring of the substrate 4 with a conductive member such as a bump and solder via the first wiring member 17, the base body 18, and the second wiring member 19. Note that the configuration, the size, and the like of the wiring of the substrate 4 are set in accordance with the configuration and the size of the electrode 16 of the light-emitting element 14.

The second covering member 15 integrally holds a plurality of first covering members 11, a plurality of light diffusion members 12, a plurality of wavelength conversion members 13, and a plurality of light-emitting elements 14. In the example illustrated in FIG. 5, the second covering member 15 is disposed on the lateral surfaces of the first covering member 11, the light diffusion member 12, the wavelength conversion member 13, and the light-emitting element 14. The second covering member 15 is disposed between adjacent first covering members 11, between adjacent light diffusion members 12, between adjacent wavelength conversion members 13, and between adjacent light-emitting elements 14, respectively. The second covering member 15 integrally holds the first covering member 11, the light diffusion member 12, the wavelength conversion member 13, and the light-emitting element 14 of the first light-emitting unit 1-1, and the first covering member 11, the light diffusion member 12, the wavelength conversion member 13, and the light-emitting element 14 included in each of the 24 second light-emitting units 1-2. A portion of an upper surface of the second covering member 15 constitutes an upper surface of the light source 1. In addition, the second covering member 15 includes two long lateral surfaces and two short lateral surfaces, and the four lateral surfaces constitute a substantially rectangular outer shape of the light source 1 in a top view.

Because the light source 1 includes the one first light-emitting unit 1-1 and the plurality of second light-emitting units 1-2, the degree of freedom in the pattern of light that can be emitted from the light source 1 is increased. In addition, with the second covering member 15 integrally holding the plurality of light-emitting elements 14 and the plurality of wavelength conversion members 13, the light source 1 can be easily mounted.

The light-emitting element 14 includes various semiconductors including a group III-V compound semiconductor and a group II-VI compound semiconductor, and the like. As the semiconductor, preferably, a nitride-based semiconductor such as In_{X}Al_{Y}Ga_{1-X-Y}N (0≤X, 0≤Y, X+Y≤1) is used, and any of InN, AlN, GaN, InGaN, AlGaN, InGaAlN, and the like can also be used. The light-emitting element 14 is an LED or a laser diode (LD), for example. The nitride-based semiconductor of the light-emitting element 14 is provided on a growth substrate such as sapphire. Note that the light-emitting element 14 may be obtained by forming a nitride-based semiconductor on the growth substrate and then removing the growth substrate. A light emission peak wavelength of the light-emitting element 14 is preferably in a range from 400 nm to 530 nm, more preferably in a range from 420 nm to 490 nm, even more preferably in a range from 450 nm to 475 nm from the viewpoints of light emission efficiency, excitation of a wavelength conversion substance described below, and the like.

The wavelength conversion member 13 is, for example, a member having a substantially rectangular shape in a top view. The wavelength conversion member 13 is provided so as to cover an upper surface of the light-emitting element 14. The wavelength conversion member 13 contains a wavelength conversion substance that converts a wavelength of at least a part of light from the light-emitting element 14. The wavelength conversion member 13 can be formed using a light-transmissive resin material or an inorganic material such as ceramics or glass. As the resin material, a thermosetting resin, such as a silicone resin, a silicone modified resin, an epoxy resin, an epoxy modified resin, or a phenol resin, can be used. Particularly, a silicone resin or a modified resin thereof with good light resistance and heat resistance is used. Note that light transmissivity here preferably refers to transmission of 60% or more of the light from the light-emitting element 14. In addition, the wavelength conversion member 13 may use a thermoplastic resin, such as a polycarbonate resin, an acrylic resin, a methyl pentene resin, or a polynorbornene resin. The wavelength conversion member 13 may be, for example, a member containing a wavelength conversion substance in a resin material, ceramics, glass, or the like, and a sintered body of the wavelength conversion substance, or the like. Further, the wavelength conversion member 13 may contain a light diffusion substance described below in the resin described above. In addition, the wavelength conversion member 13 may also be a multilayer in which a resin layer containing the wavelength conversion substance or the light diffusion substance is disposed on a +Z side surface of a molded body of resin, ceramics, glass, or the like.

As the wavelength conversion substance contained in the wavelength conversion member 13, an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), an oxynitride-based phosphor such as a β-SiAlON-based phosphor (for example, (Si,Al)₃(O,N)₄:Eu) or an α-SiAlON-based phosphor (for example, Ca(Si,Al)₁₂(O,N)₁₆:Eu), a nitride-based phosphor such as an LSN-based phosphor (for example, (La,Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca)AlSiN₃:Eu), a fluoride-based phosphor such as a KSF-based phosphor (for example, K₂SiF₆:Mn), a KSAF-based phosphor (for example, K₂(Si₁₋ₓAlₓ)F^{6-x}:Mn, where x satisfies 0<x<1), or an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a group II-VI quantum dot (for example, CdSe), a group III-V quantum dot (for example, InP), a quantum dot having a chalcopyrite structure (for example, (Ag,Cu)(In,Ga)(S,Se)₂), or the like can be used. The wavelength conversion substance described above is in the form of particles. Further, one type of these wavelength conversion substances can be used alone, or two or more types of these wavelength conversion substances can be used in combination.

Because the light-emitting unit 1B includes the light-emitting element 14 and the wavelength conversion member 13, the light-emitting unit 1B can emit mixed-color light including a color of light emitted from the light-emitting element 14 and a color of light emitted from the wavelength conversion member 13. In the light-emitting unit 1B, a degree of freedom in a color of light emitted from the light-emitting unit 1B can be increased by a combination of the light-emitting element 14 and the wavelength conversion member 13.

In the present embodiment, the light source 1 uses a blue LED as the light-emitting element 14, and the wavelength conversion member 13 contains a wavelength conversion substance that converts the wavelength of the light emitted from the light-emitting element 14 into yellow light. Thus, the light source 1 emits white light. The wavelength or chromaticity of light emitted from the light source 1 may be appropriately selected in accordance with an application of the light-emitting module 100.

The light diffusion member 12 is a member that diffuses light from the light-emitting element 14 and the wavelength conversion member 13, and is, for example, a member having a substantially rectangular shape in a top view. As the light diffusion member 12, for example, a resin material containing a light diffusion substance can be used. As the light diffusion substance included in the light diffusion member 12, examples include titanium oxide, barium titanate, aluminum oxide, silicon oxide, and the like, and one of these substances may be used alone, or two or more of these substances may be used in combination. The resin material is preferably a material in which a resin material including a thermosetting resin, such as an epoxy resin, an epoxy modified resin, a silicone resin, a silicone modified resin, a phenol resin, or the like, as a main component is used as a base material.

The second covering member 15 covers the lateral surfaces of the first covering member 11, the light diffusion member 12, the wavelength conversion member 13, and the light-emitting element 14. The second covering member 15 directly or indirectly covers the lateral surfaces of the first covering member 11, the light diffusion member 12, the wavelength conversion member 13, and the light-emitting element 14. The second covering member 15 is preferably formed of a member having high light reflectivity. Covering the first covering member 11, the light diffusion member 12, the wavelength conversion member 13, and the light-emitting element 14 with the second covering member 15 can reduce light leaking from these members, and light can be efficiently extracted from the light-emitting surface 10. This increases light extraction efficiency of the light-emitting unit 1B. The second covering member 15 may use, for example, a resin material containing a light-reflective substance, such as a white pigment. Alternatively, the second covering member 15 may also be a light-reflective member formed of an inorganic material containing, for example, boron nitride or alkali metal silicate. In this case, titanium oxide or zirconium oxide can be further contained.

Examples of the light-reflective substance contained in the second covering member 15 include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, silicon oxide, and the like, and it is preferable to use one of these substances alone, or two or more of these substances in combination. The resin material is preferably a material in which a resin material including a thermosetting resin, such as an epoxy resin, an epoxy modified resin, a silicone resin, a silicone modified resin, a phenol resin, or the like, as a main component is used as a base material. Note that the second covering member 15 may be configured using a member having transmissivity or light absorbency for visible light as necessary. The member having the light absorbency contains, for example, carbon black.

The first covering member 11 is a member covering at least a portion of an upper surface of light diffusion member 12, and is, for example, a member having a substantially rectangular shape in a top view. By disposing the first covering member 11, the upper surface of the light diffusion member 12 can be protected from external force or the like. In the present embodiment, an upper surface of the first covering member 11 illustrated in FIG. 5 is exposed from the second covering member 15 and serves as the light-emitting surface 10. The first covering member 11 can be configured to include a material similar to the material exemplified for the second covering member 15.

The base body 18 is a member formed using ceramics as a main material. Examples of the ceramics include, for example, aluminum nitride, silicon nitride, aluminum oxide, silicon carbide, and the like. In the present embodiment, the light source 1 is mounted on the substrate 4 via the base body 18, so that the heat dissipation of the light-emitting module 100 is improved.

In the light source 1, the first covering member 11 has a thickness in a range from 1 μm to 100 μm, the light diffusion member 12 has a thickness in a range from 10 μm to 200 μm, the wavelength conversion member 13 has a thickness in a range from 20 μm to 200 μm, the light-emitting element 14 has a thickness in a range from 5 μm to 50 μm, and the base body 18 has a thickness in a range from 150 μm to 1000 μm. In addition, an interval Gp between adjacent light-emitting elements 14 is in a range from 5 μm to 100 μm. In the present embodiment, the light-emitting element 14 is manufactured by a laser lift off (LLO) processing method. Here, the LLO processing method refers to a processing method in which a high-power laser is irradiated onto a processing target to heat and decompose a processing surface of the processing target, thereby separating one or more members into two or more members at the processing surface as a boundary. For example, the process of manufacturing the light-emitting element 14 includes a process of separating the growth substrate of the light-emitting element from the nitride-based semiconductor by the LLO processing method. By manufacturing the light-emitting element 14 from which the growth substrate such as sapphire is removed by the LLO processing method, the thickness of the light-emitting element 14 is reduced, and light generated in the nitride-based semiconductor of the light-emitting element 14 and absorbed mainly by the growth substrate can be effectively used. That is, the light absorbed in the light-emitting element 14 is reduced, and the light extraction efficiency is improved. Accordingly, the optical output from the light-emitting element 14 is increased. Note that the light-emitting module 100 may use the light source 1 that does not include the base body 18. In this case, the LLO processing method may be omitted, and the light-emitting element 14 including a growth substrate may be used. In the light source 1 not having the base body 18, the electrode 16 of the light-emitting element 14 and the wiring of the substrate 4 are electrically connected by being connected via a conductive member such as a bump and solder.

### Lens 2

The lens 2 is formed to include at least one of a resin material, such as a polycarbonate resin, an acrylic resin, a silicone resin, or an epoxy resin, and a glass material, which is light-transmissive with respect to the light emitted from the light source 1. The first light-transmissive portion 20 and the first support portion 25 are connected to each other as an integrated member. However, the first light-transmissive portion 20 and the first support portion 25 may be separate members. In addition, the first support portion 25 may be omitted, and the first light-transmissive portion 20 may also function as the first support portion 25. Note that the transmissivity of the lens 2 refers to a property of transmitting 60% or more of light from the light source 1.

In the example illustrated in FIG. 1, the first light-transmissive portion 20 has a substantially circular shape in a top view. However, the first light-transmissive portion 20 in a top view is not limited to a substantially circular shape, and may be a substantially rectangular shape, a substantially elliptical shape, a substantially polygonal shape, or the like. Further, the first light-transmissive portion 20 may have a rotationally symmetrical shape in a top view. In consideration that a field of view of a general imaging device is substantially rectangular, it is preferable that a first light-transmissive portion 20 has a four-fold rotationally symmetrical shape or a two-fold rotationally symmetrical shape in a top view.

In the example illustrated in FIG. 2, the annular convex surface 211 on the light incident surface 21 is a convex surface that is convex toward a side where the light source 1 is located. The annular convex surface 221 on the light exiting surface 22 is a convex surface that is convex toward a side opposite to the side where the light source 1 is located. The first light-transmissive portion 20 is a biconvex single lens in which the through hole 23 is formed at the center thereof. Each of the annular convex surface 211 and the annular convex surface 221 is a spherical surface. However, at least one of the light incident surface 21 and the light exiting surface 22 of the first light-transmissive portion 20 may be a concave surface. The first light-transmissive portion 20 may be a meniscus single lens in which the through hole 23 is formed at the center thereof. The annular convex surface 211 and the annular convex surface 221 are not limited to spherical surfaces and may be aspherical surfaces.

The through hole 23 illustrated in FIG. 1 is substantially circular in a top view. In addition, as illustrated in FIG. 2, in a cross section parallel to the Z-axis passing through the central axis 20C, the through hole 23 is a hole whose inner lateral surface 23a is along the central axis 20C of the first light-transmissive portion 20. The through hole 23 is a tapered hole whose inner lateral surface narrows in a direction opposite to the direction toward the light source 1 (in other words, in the direction in which light is emitted from the light-emitting module 100). In the through hole 23, an area of the first opening 231 is greater than an area of the second opening 232. Accordingly, the light distribution of light passing through the through hole 23 can be narrowed. Alternatively, the through hole 23 may be a tapered hole whose inner lateral surface narrows in a direction toward the light source 1 is located, or may be a hole parallel to the central axis 20C of the first light-transmissive portion 20.

In the example illustrated in FIG. 1, the first support portion 25 is a cylindrical portion that supports the first light-transmissive portion 20 from the outside in a top view. In addition, the first support portion 25 has a continuous circular annular shape in a top view. The first support portion 25 is not limited to having a circular annular shape in a top view, and may have a rectangular annular shape or a polygonal annular shape. In addition, the first support portion 25 may include a plurality of first support portions 25, and the plurality of first support portions 25 may be annularly disposed in a top view.

### Substrate 4

The substrate 4 is a substrate including a wiring line, on which the light source 1 can be mounted. In the examples illustrated in FIG. 1 and FIG. 2, the substrate 4 is a plate-shaped member having a substantially circular shape in a top view. Note that the substrate 4 may be a substantially rectangular shape, a substantially elliptical shape, a substantially polygonal shape, or the like in a top view. In addition, on the substrate 4, an electronic component other than the light source 1 may be further disposed. The electronic component is a Zener diode, a thermistor, a capacitor, a light-receiving sensor, or the like.

It is preferable that a substrate 4 use an insulation material as a base material, and also use a material that is less likely to transmit light emitted from the light source 1 or light incident into an interior of the light-emitting module 100 from outside. Further, for the substrate 4, a material having a certain degree of strength is preferably used. Specifically, the substrate 4 can be formed using ceramics, such as alumina, aluminum nitride, mullite, or silicon nitride, or a resin, such as a phenol resin, an epoxy resin, a polyimide resin, a bismaleimide triazine resin (BT resin), a polyphthalamide, or a polyester resin, as the base material.

The wiring of the substrate 4 can be made of at least one type of copper, iron, nickel, tungsten, chromium, aluminum, silver, gold, titanium, palladium, rhodium, alloys thereof, or the like. In addition, on a surface layer of the wiring of the substrate 4, a layer of silver, platinum, aluminum, rhodium, gold, or alloys thereof, or the like may be provided from the viewpoint of at least one of wettability and light reflectivity.

### Modified Example of First Embodiment

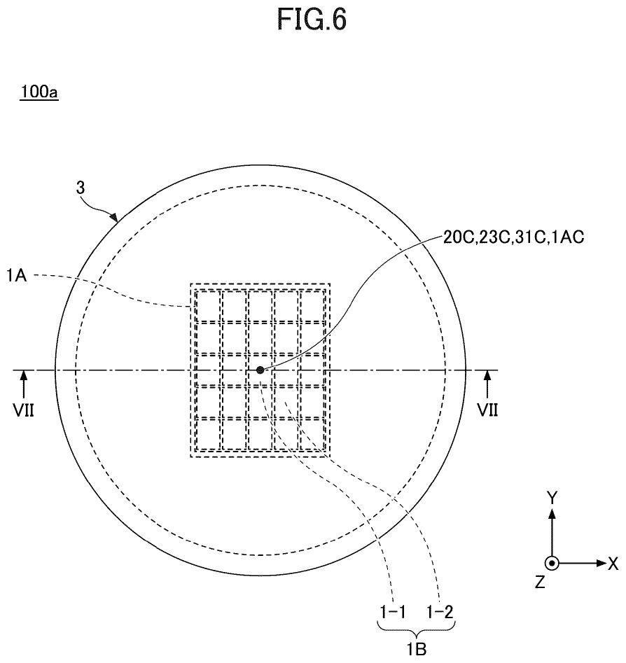

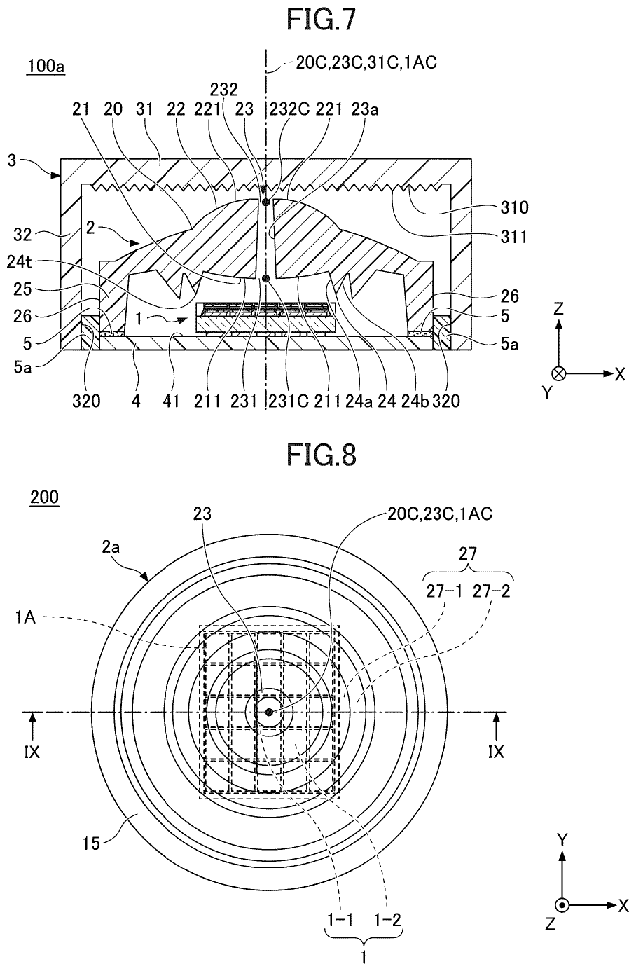

A light-emitting module 100a, which is a modified example of the first embodiment, will be described. FIG. 6 is a schematic top view of the light-emitting module according to the modified example of the first embodiment. FIG. 7 is a schematic cross-sectional view taken along line VII-VII in FIG. 6. The light-emitting module 100a is different from the light-emitting module 100 mainly in that the light-emitting module 100a further includes a light-transmissive member 3.

FIGS. 6 and 7 illustrates the light-emitting module 100a according to the modified example of the first embodiment. In the example illustrated in FIG. 6, an outer shape of the light-emitting module 100a is a substantially circular shape in a top view. In a top view, the outer shape of the light-transmissive member 3 is the outer shape of the light-emitting module 100a. However, the outer shapes of the light-emitting module 100a and the light-transmissive member 3 are not limited to substantially circular shapes in a top view and may have other shapes such as substantially elliptical shapes, substantially rectangular shapes, or substantially polygonal shapes. In the example illustrated in FIGS. 6 and 7, the light-emitting module 100a further includes an adhesive member 5a that is disposed between the substrate 4 and the first support portion 25 and an inner lateral surface 320 of the light-transmissive member 3.

In the light-emitting module 100a, the light-transmissive member 3 includes a second light-transmissive portion 31 and a second support portion 32 that supports the second light-transmissive portion 31. The second light-transmissive portion 31 faces the light exiting surface of the lens 2. The first support portion 25 is fixed to the second support portion 32. With the light-emitting module 100a including the light-transmissive member 3, light distribution can be controlled using the first light-transmissive portion 20 of the lens 2 and the second light-transmissive portion 31 of the light-transmissive member 3, so that a degree of freedom in light distribution control increases. In addition, by fixing the first support portion 25 to the second support portion 32, the first support portion 25 can be stably fixed.

### Light-Transmissive Member 3

The light-transmissive member 3 is disposed so as to cover the lens 2. The second light-transmissive portion 31 transmits light that is emitted from the light source 1 and has passed through the lens 2. The light-transmissive member 3 is configured to include at least one of a resin material, such as a polycarbonate resin, an acrylic resin, a silicone resin, or an epoxy resin, and a glass material, which are light-transmissive with respect to the light emitted from the light source 1. The transmissivity of the second light-transmissive portion 31 is preferably a property of transmitting 60% or more of light from the light source 1.

In the example illustrated in FIG. 7, the second light-transmissive portion 31 and the second support portion 32 are integrally formed together as a single monolithic component, that is, without using an adhesive member. From another viewpoint, the second light-transmissive portion 31 is continuous with the second support portion 32. However, the second light-transmissive portion 31 and the second support portion 32 may be separate members bonded together via an adhesive member.

In the example illustrated in FIGS. 6 and 7, the second light-transmissive portion 31 of the light-transmissive member 3 has a light incident surface 310 facing the light exiting surface 22 of the lens 2. The light incident surface 310 includes a plurality of concentric protrusions 311 centered on a central axis 31C of the second light-transmissive portion 31. The central axis 31C of the second light-transmissive portion 31 overlaps, in a top view, the central axis 20C of the first light-transmissive portion 20 and the center 1AC of the light-emitting region 1A of the light source 1. The protrusion 311 may be a Fresnel lens having a Fresnel shape. However, the protrusion 311 is not limited to the Fresnel lens, and may be a lens of other shapes such as a biconvex single lens, a planoconvex single lens, a biconcave single lens, a planoconcave single lens, an array lens, a meniscus single lens, an aspherical lens, or a cylindrical lens.

The second support portion 32 supports the second light-transmissive portion 31 such that the second light-transmissive portion 31 is disposed above the first light-transmissive portion 20. The second support portion 32 is a circular annular portion, in a top view, of the light-transmissive member 3. The second support portion 32 is a cylindrical portion that extend downward outside the substrate 4 and outside the lens 2. The second support portion 32 is disposed such that a part of the inner lateral surface 320 faces an outer lateral surface 26 of the first support portion 25 of the lens 2, and a part of the inner lateral surface 320 and an outer lateral surface 26 of the first support portion 25 are bonded together by the adhesive member 5a. By bonding the second support portion 32 and the first support portion 25, the light-transmissive member 3 and the lens 2 are bonded together. The adhesive member 5a does not need to be located between the first support portion 25 and the second support portion 32 as long as the adhesive member 5a fixes at least the substrate 4 and the light-transmissive member 3 together.

### Second Embodiment

Next, a light-emitting module 200 including a lens 2a according to a second embodiment will be described. The same names and reference characters as those in the previously described embodiment indicate the same members or configurations or members or configurations made of the same material, and detailed descriptions thereof are omitted as appropriate. This applies similarly to the embodiments and examples described below.

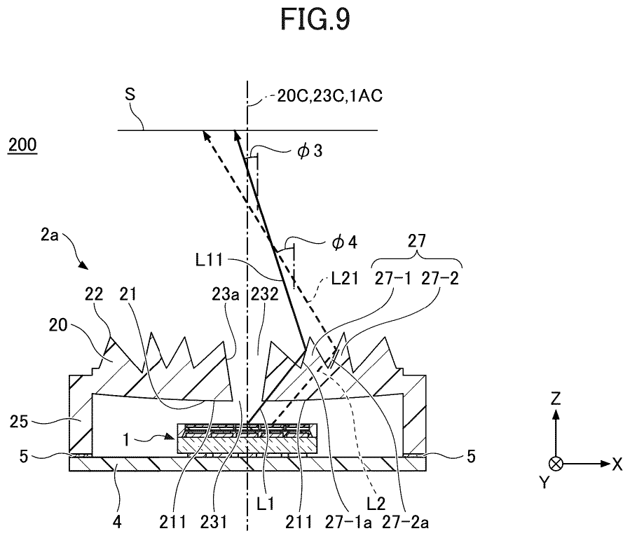

FIG. 8 is a schematic top view of the light-emitting module 200 including the lens 2a according to the second embodiment. FIG. 9 is a schematic cross-sectional view taken along line IX-IX in FIG. 8, and illustrates behaviors of light L1 and light L2 exited from the lens 2a according to the second embodiment. Note that, in FIG. 9, a part of light beams (first light beam L11) of the light L1 emitted from the first light-emitting unit 1-1 is illustrated by a solid line arrow. In addition, one of light beams (second light beam L21) of the light L2 emitted from the second light-emitting unit 1-2 is illustrated by a broken line arrow.

The light-emitting module 200 including the lens 2a according to the second embodiment includes a light source 1 and the lens 2a. In the present embodiment, a light exiting surface 22 of a first light-transmissive portion 20 included in the lens 2a includes at least one annular protrusion 27 centered on a central axis 20C of the first light-transmissive portion 20. The at least one annular protrusion 27 includes an annular first protrusion 27-1 that can guide light to have a first light distribution angle, and an annular second protrusion 27-2 surrounding the annular first protrusion 27-1 in a top view and can guide light to have a second light distribution angle greater than the first light distribution angle. The lens 2a according to the present embodiment is different from the lens 2 according to the first embodiment in the configurations described above.

In the examples illustrated in FIGS. 8 and 9, the light exiting surface 22 of the first light-transmissive portion 20 includes four annular protrusions 27 concentric with the central axis 20C of the first light-transmissive portion 20. The annular first protrusion 27-1 that can guide light to have the first light distribution angle is the annular protrusion 27 located at the second position when counted from the innermost side toward the outer side. The annular second protrusion 27-2 that can guide light at the second light distribution angle is the annular protrusion 27 located at the third position when counted from the innermost side toward the outer side. In the example illustrated in FIG. 9, a part of the light L1 emitted from the first light-emitting unit 1-1 is reflected at an inner lateral surface 27-1a, so that the annular first protrusion 27-1 guide the light to have the first light distribution angle. A part of the light L2 emitted from the second light-emitting unit 1-2 is reflected at an inner lateral surface 27-2a, so that the annular second protrusion 27-2 guides the light to have the second light distribution angle. The second light distribution angle is greater than the first light distribution angle.

The light emitted from the first light-emitting unit 1-1 and refracted or reflected by the first protrusion 27-1 includes the first light beam L11. The light emitted from the second light-emitting unit 1-2 and refracted or reflected by the second protrusion 27-2 includes the second light beam L21. An angle φ4 formed by the second light beam L21 and the central axis 20C of the first light-transmissive portion 20 is greater than an angle φ3 formed by the first light beam L11 and the central axis 20C of the first light-transmissive portion 20. In the example illustrated in FIG. 9, the first light beam L11 is light reflected by the inner lateral surface 27-1a of the first protrusion 27-1. The second light beam L21 is the light reflected by the inner lateral surface 27-2a of the second protrusion 27-2.

The light incident surface 21 of the first light-transmissive portion 20 has an annular convex surface 211 surrounding a through hole 23 in a top view. The through hole 23 is a tapered hole including a first opening 231 located at the light incident surface 21 and a second opening 232 located at the light exiting surface 22, and the area of the first opening 231 is smaller than the area of the second opening 232. In other words, the through hole 23 is a tapered hole whose inner lateral surface 23a narrows in a direction toward the light source 1. This enables, for example, light distribution control in accordance with the inclination angle of the inner lateral surface 23a with respect to the central axis 20C of the first light-transmissive portion 20. Note that the through hole 23 may be the tapered hole in which the inner lateral surface 23a narrows in a direction opposite to the direction toward the light source 1, or may be the parallel hole.

In the present embodiment, the annular convex surface 211 includes a gentle curved surface that is convex toward the light source 1. Accordingly, light emitted from the light source 1 and traveling outward is refracted by the annular convex surface 211 toward the central axis 20C of the first light-transmissive portion 20, allowing for increasing an amount of light that is refracted or reflected by the first protrusion 27-1 and the second protrusion 27-2. Note that the annular convex surface 211 may include a flat surface as long as the annular convex surface 211 is convex toward the light source 1.

In the present embodiment, in the lens 2a, the through hole 23 is formed in the first light-transmissive portion 20, and the first light-transmissive portion 20 includes the first protrusion 27-1 and the second protrusion 27-2 at the light exiting surface 22. Thus, the light distribution of light passing through the through hole 23 can be different from the light distribution of light passing through the portion other than the through hole 23. The through hole 23 reflects a part of the light L1 emitted from the first light-emitting unit 1-1 on the inner lateral surface 23a to guide the light to have a third light distribution angle. Therefore, the first light distribution angle is greater than the third light distribution angle, and the second light distribution angle is greater than the first light distribution angle. In the present embodiment, the light distribution of light passing through the through hole 23 is different from the light distribution of light passing through the portion other than the through hole 23, so that the lens 2a configured to control light distribution can be provided. By increasing a distance between the light source 1 and the lens 2a, light passing through the through hole 23 becomes easier to control, and a narrow-angle light distribution can be achieved. Further, in the present embodiment, the light-emitting module 200 including the lens 2a and for performing light distribution control can be provided.

The number of annular protrusions 27 provided on the light exiting surface 22 is not limited to four and may be any number. As long as the annular second protrusion 27-2 is in a positional relationship in which the annular second protrusion 27-2 surrounds the annular first protrusion 27-1, the positions of the annular first protrusion 27-1 and the annular second protrusion 27-2 can be appropriately determined. The outer lateral surface of the annular first protrusion 27-1 may reflect or refract the light L1. The outer lateral surface of the annular second protrusion 27-2 may reflect or refract the light L2.

In the present embodiment, the first light-transmissive portion 20 and a first support portion 25 are continuous with each other as a monolithic member. Alternatively, the first light-transmissive portion 20 and the first support portion 25 may be separate members. In addition, the first support portion 25 may be omitted, and the first light-transmissive portion 20 may also function as the first support portion 25.

Further, the light-emitting module 200 may further include a light-transmissive member 3 disposed to cover the lens 2a. As the light-transmissive member 3, the light-transmissive member 3 illustrated in FIGS. 6 and 7 may be applied.

### Third Embodiment

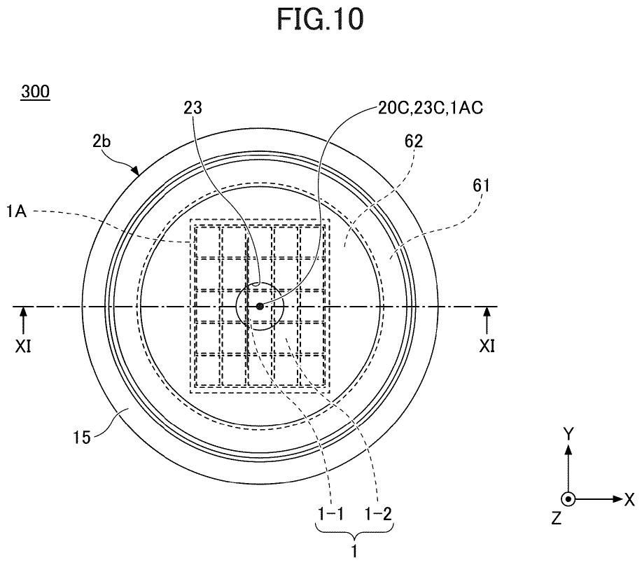

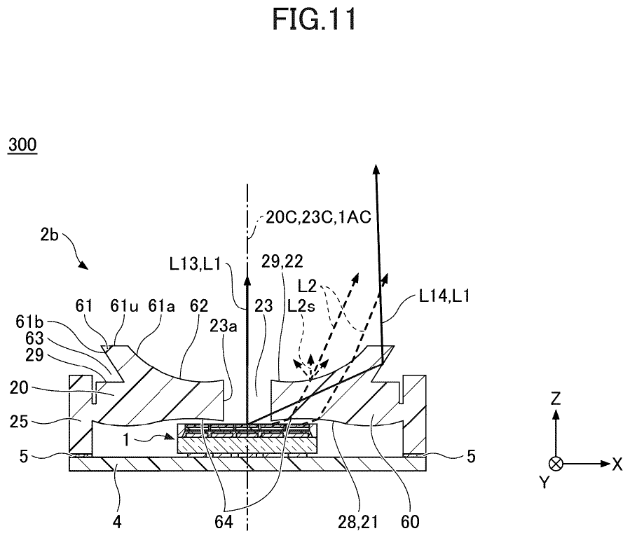

Next, a light-emitting module 300 including a lens 2b according to a third embodiment will be described with reference to FIGS. 10 and 11. FIG. 10 is a schematic top view of the light-emitting module 300 including the lens 2b according to the third embodiment. FIG. 11 is a schematic cross-sectional view taken along line XI-XI in FIG. 10, and is a diagram illustrating behavior of light L1 and light L2 exiting from the lens 2b. Note that, in FIG. 11, a part of light beams of the light L1 emitted from the first light-emitting unit 1-1 is indicated by solid line arrows. Further, a part of light beams of the light L2 emitted from the second light-emitting unit 1-2 is indicated by broken line arrows.

In the present embodiment, a first light-transmissive portion 20 of the lens 2b includes a main body portion 60 having a first main surface 28 including a light incident surface 21 and a second main surface 29 located at a side opposite to the first main surface 28, and an annular protrusion 61 disposed on the second main surface 29 of the main body portion 60. The protrusion 61 has an annular shape centered on a central axis 20C of the first light-transmissive portion 20. The annular protrusion 61 has an inner lateral surface 61a located on a side of a through hole 23 and an outer lateral surface 61b located outside the inner lateral surface 61a. The first light-transmissive portion 20 is composed of the inner lateral surface 61a of the annular protrusion 61 and the second main surface 29 of the main body portion 60 on the light exiting surface 22, and includes an annular first concave surface 62 that surrounds the through hole 23. The lens 2b according to the present embodiment is different from the lens 2 according to the first embodiment in the above points.

An air layer 63 is present between the outer lateral surface 61b of the annular protrusion 61 and the second main surface 29 of the main body portion 60. The air layer 63 can also be referred to as a space. In the example illustrated in FIG. 11, the protrusion 61 includes a flat upper surface 61u. The upper surface 61u has an annular shape centered on the central axis 20C of the first light-transmissive portion 20. The inner lateral surface 61a of the protrusion 61 is included in the second main surface 29. A part of the annular first concave surface 62 constitutes the inner lateral surface 61a of the protrusion 61.

The light L1 emitted from the first light-emitting unit 1-1 includes light L13 irradiated through the through hole 23 and light L14 refracted or reflected by the outer lateral surface 61b of the annular protrusion 61. In the example illustrated in FIG. 11, the through hole 23 is a hole whose inner lateral surface 23a is parallel to the central axis 20C of the first light-transmissive portion 20. By the inner lateral surface 23a of the through hole 23 being parallel to the central axis 20C, an excessive widening of light distribution of light passing through the through hole 23 and a decrease in illuminance of the light passing through the through hole 23 can be reduced. In the example illustrated in FIG. 11, the light L13 travels along a central axis 23C of the through holes 23. The light L14, after being incident on the inner lateral surface 23a of the through hole 23 and passing through an interior of the main body portion 60 and an interior of the protrusion 61, is reflected by the outer lateral surface 61b of the protrusion 61 and exits from the upper surface 61u of the protrusion 61. The through hole 23 may be a tapered hole whose inner lateral surface narrows in a direction opposite to the direction toward a light source 1, or may be a tapered hole whose inner lateral surface narrows in the direction toward the light source 1. This allows adjustment of the light distribution of light passing through the through hole 23.

The light incident surface 21 of the first light-transmissive portion 20 has an annular second concave surface 64 at a position overlapping the second light-emitting unit 1-2 in a top view. In the example illustrated in FIG. 11, the annular second concave surface 64 surrounds the through hole 23 in the light incident surface 21 and includes a portion facing the second light-emitting unit 1-2.

In the example illustrated in FIG. 11, the light L2 emitted from the second light-emitting unit 1-2 is incident on the second concave surface 64 of the first main surface 28 and refracted in a direction away from the central axis 20C of the first light-transmissive portion 20. The light L2 is transmitted through the interior of the main body portion 60 and then exits from the first concave surface 62 and the inner lateral surface 61a of the protrusion 61. At least a part of the light L2 emitted from the second light-emitting unit 1-2 is subjected to a diffusion action by the annular first concave surface 62 and the concave surface included in the inner lateral surface 61a of the protrusion 61, and is refracted in a direction away from the central axis 20C of the first light-transmissive portion 20. Thus, in the present embodiment, irradiation of light with the wide-angle light distribution can be performed.

In addition, at least a part of the light L2 emitted from the second light-emitting unit 1-2 is diffused by the annular first concave surface 62. In the example illustrated in FIG. 11, the light L2 emitted from the second light-emitting unit 1-2, after being incident on the first main surface 28 and passing through the interior of the main body portion 60, exits from the first concave surface 62. The light L2 is diffused upon exiting from the first concave surface 62. In FIG. 11, among the light L2 emitted from the second light-emitting unit 1-2, diffused light L2s that has been diffused by the annular first concave surface 62 is indicated by broken line arrows. The degree of diffusion at the first concave surface 62 can be adjusted by surface roughness or the like of the first concave surface 62.

As described above, in the present embodiment, at least a part of the light L2 emitted from the second light-emitting unit 1-2 is diffused by the annular first concave surface 62. Accordingly, the light distribution angle of the light L2 from the second light-emitting unit 1-2 can be increased.

In the present embodiment, an air layer 63 is present between the outer lateral surface 61b of the annular protrusion 61 and the second main surface 29 of the main body portion 60. Thus, the light L1 that passes through the interior of the annular protrusion 61 and is incident on the outer lateral surface 61b is reflected by the outer lateral surface 61b and can be caused to travel toward the central axis 20C of the first light-transmissive portion 20. In the present embodiment, by irradiating narrow-angle mode light via an annular protrusion 61, light having a narrower narrow-angle light distribution can be irradiated as compared with a case in which irradiation is performed without passing through the annular protrusion 61.

In the present embodiment, the light L1 emitted from the first light-emitting unit 1-1 includes the light L13 irradiated through the through hole 23 and the light L14 refracted or reflected by the outer lateral surface 61b of the annular protrusion 61. By using not only the light L13 but also the light L14, light extraction efficiency is improved.

In the present embodiment, the through hole 23 is formed in the first light-transmissive portion 20, and the first light-transmissive portion 20 includes the annular first concave surface 62 surrounding the through hole 23 on the light exiting surface 22. Thus, the light distribution of light passing through the through hole 23 can be made different from the light distribution of light passing through the portion other than the through hole 23. In the present embodiment, by the light distribution of light passing through the through hole 23 being different from that of light passing through the portion other than the through hole 23, the lens 2b for performing light distribution control can be provided. Further, in the present embodiment, the light-emitting module including the lens 2b for performing light distribution control can be provided.

As described above, in a case in which the light incident surface 21 of the first light-transmissive portion 20 has the annular second concave surface 64 at a position overlapping the second light-emitting unit 1-2 in a top view, light from the light source 1 that is totally reflected at the light incident surface 21 and does not enter the first light-transmissive portion 20 can be reduced. That is, in the light incident surface 21 of the first light-transmissive portion 20, the configuration having the annular second concave surface 64 at the position overlapping the second light-emitting unit 1-2 in a top view increases the amount of light taken into the first light-transmissive portion 20, thereby increasing the light extraction efficiency, and the light incident on the first light-transmissive portion 20 is more likely to spread, as compared with the configuration having a flat surface parallel to a light-emitting surface 10 of the light source 1. Note that the light incident surface 21 of the first light-transmissive portion 20 may be a flat surface parallel to the light-emitting surface 10 of the light source 1.

The light-emitting module 300 including the lens 2b according to the third embodiment can further include a light-transmissive member 3 disposed so as to cover the lens 2b. As the light-transmissive member 3, the light-transmissive member 3 illustrated in FIGS. 6 and 7 may be applied.

### Examples and Reference Examples

Examples and Reference Examples will be described below. However, the present disclosure is not limited to these examples.

In the examples and reference examples, items (1) to (4) below were evaluated in the light-emitting modules according to each of Example 1, Example 2, Example 3, Reference Example 1, and Reference Example 2. Note that FOV stands for Field Of View.
(1) Center illuminance (lux) on the irradiation surface located 1 m away from the exiting surface of the light-emitting module
(2) FOV0°
(3) FOV45°
(4) FOV90°

With respect to the above item (1), center illuminance (lux) in the narrow-angle light distribution, the wide-angle light distribution, and the ultra-wide-angle light distribution was evaluated. In the light-emitting modules according to each of Example 1, Example 2, Example 3, Reference Example 1, and Reference Example 2, the narrow-angle mode for irradiating the narrow-angle light distribution was specified to either a mode (A) in which some of the 24 second light-emitting units 1-2 and the first light-emitting unit 1-1 were caused to emit light, or a mode (B) in which only the first light-emitting unit 1-1 was caused to emit light and the second light-emitting unit 1-2 was not caused to emit light. Also, in the light-emitting module according to each of Example 1, Example 2, Example 3, Reference Example 1, and Reference Example 2, the wide-angle mode for irradiating the wide-angle light distribution or the ultra-wide-angle light distribution was specified as any one of a mode (a) in which only some of the 24 second light-emitting units 1-2 were caused to emit light, a mode (b) in which all of the 24 second light-emitting units 1-2 were caused to emit light, and a mode (c) in which all of the 24 second light-emitting units 1-2 and the first light-emitting unit 1-1 were caused to emit light. Table 1 shows the specifications of the light-emitting modules according to each of Example 1, Example 2, Example 3, Reference Example 1, and Reference Example 2. Note that, in Example 2, the current values applied to the 24 second light-emitting units 1-2 were different between the wide-angle light distribution and the ultra-wide-angle light distribution.

TABLE 1

| | Specification | | |
|---|---|---|---|
| | Narrow-angle light | Wide-angle light | Ultra-wide-angle |
| | distribution | distribution | light distribution |
| Example 1 | A | c | b |
| Example 2 | A | b | b |
| Example 3 | A | b | a |
| Reference | A | a | b |
| Example 1 | | | |
| Reference | A | c | b |
| Example 2 | | | |

The above items (2) to (4) are evaluations of a viewing angle θ (hereinafter also referred to as an irradiation angle θ) of the irradiation light of the narrow-angle light distribution in an irradiation region SP when the light-emitting module according to each of Example 1, Example 2, Example 3, Reference Example 1, and Reference Example 2 is used as a light source for a flashlight. In the light-emitting modules according to each of the examples, the narrow-angle mode for irradiating the narrow-angle light distribution was specified as the mode (B) in which only the first light-emitting unit 1-1 was caused to emit light and the second light-emitting unit 1-2 was not caused to emit light.

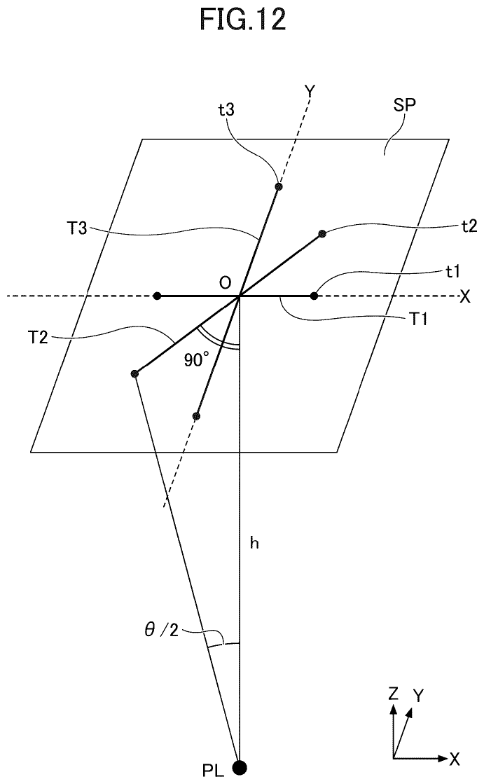

Here, a method of evaluating items (2) to (4) will be described with reference to FIG. 12. FIG. 12 is a diagram illustrating an irradiation angle θ of light emitted from a light source PL. FIG. 12 illustrates the irradiation region SP on an irradiation surface of light emitted by the light source PL. The irradiation region SP was defined as a region illustrated in a rectangular shape.

The irradiation angle θ refers to an angle at which the illuminance in the irradiation region SP becomes 10% with respect to the maximum illuminance of 100% in the irradiation region SP (in other words, on the XY plane of the irradiation region SP or on the irradiation surface). For example, as illustrated in FIG. 12, when the irradiation region SP is irradiated with light from the light source PL located at a distance h in the vertical direction (Z-axis direction) from a central position O of the irradiation region SP, which is the irradiation range, the maximum illuminance is obtained at the central position O of the irradiation range. When the illuminance at the central position O is 100%, a position at which the illuminance becomes 10% in the irradiation region SP is defined as an outer edge position t. In the present example, the items (2) to (4) were evaluated by calculating the irradiation angle θ that was defined based on the positional relationship between the two outer edge positions t and the light source PL, and the smaller irradiation angle θ is regarded as more preferable.

In the item (2), FOV0® is defined such that, in the irradiation region SP, a position at which illuminance becomes 10% in a direction parallel to the X-axis passing through the central position O (0° direction) is defined as an outer edge position t1, and a distance T between two outer edge positions t1 is defined as T1. In the item (3), FOV45° is defined such that, in the irradiation region SP, a position at which illuminance becomes 10% in a direction inclined at 45° with respect to the X-axis and passing through a central position O (45° direction) is defined as an outer edge position t2, and a distance T between two outer edge positions t2 is defined as T2. In the item (4), FOV90° is defined such that, in the irradiation region SP, a position at which illuminance becomes 10% in a direction perpendicular to the X-axis and passing through a central position O (90° direction or a direction parallel to the Y-axis) is defined as an outer edge position t3, and a distance T between two outer edge positions t3 is defined as T3. In the items (2) to (4), as an example, the distance h is set to 150 mm, and respective distances T (T1, T2, and T3) are substituted into the following Equation (1) to calculate the irradiation angle θ of irradiation light in the narrow-angle light distribution. Note that FIG. 12 illustrates, as an example, a case of calculating an irradiation angle θ of FOV45° in the item (3).

$$\begin{matrix}Equation 1 & \\ θ = 2 \times Arctan \frac{T / 2}{h} \times 180 / π & ( 1 )\end{matrix}$$

### Evaluation Results

Table 2 shows the evaluation results of each of the light-emitting modules according to Example 1, Example 2, Example 3, Reference Example 1, and Reference Example 2. Note that meanings of “Very good,” “Good,” and “Poor” in Table 2 are as follows. In addition, the target value of the item (1) means an illuminance at which a sufficient amount of light can be provided to the irradiation region in the wide-angle mode or the narrow-angle mode. The target values of the items (2) to (4) mean that the irradiation angle θ of the irradiation light is a sufficiently small value in a case in which the light-emitting module is used as a light source for a flashlight.
“Very good”: sufficiently satisfies the target value.
“Good”: satisfies the target value.
“Poor”: does not satisfy the target value.

TABLE 2

| | | | | | Reference | Reference |
|---|---|---|---|---|---|---|
| Item | | Example 1 | Example 2 | Example 3 | Example 1 | Example 2 |
| Center | Narrow- | Very good | Very good | Very good | Very good | Very good |
| illuminance | angle light | | | | | |
| [lux] at 1 m | distribution | | | | | |
| away | Wide-angle | Good | Good | Very good | Good | Poor |
| | light | | | | | |
| | distribution | | | | | |
| | Ultra-wide- | Very good | Very good | Very good | Good | Poor |
| | angle light | | | | | |
| | distribution | | | | | |

| | | | | | |
|---|---|---|---|---|---|
| FOV 0° | Very good | Good | Good | Good | Very good |
| FOV 45° | Very good | Good | Good | Good | Very good |
| FOV 90° | Very good | Good | Good | Poor | Very good |

### Example 1

Example 1 evaluated optical characteristics of the light-emitting module 100a according to the modified example of the first embodiment. The material of the lens 2 and the light-transmissive member 3 of the light-emitting module 100a was polycarbonate resin. In Example 1, the illuminance in the narrow-angle light distribution and the illuminance in the ultra-wide-angle light distribution were rated as “Very good.” The illuminance in the wide-angle light distribution was rated as “Good.” Each of FOV0®, FOV45°, and FOV90° was rated as “Very good.” Therefore, in Example 1, all of the items satisfied the target values.

### Example 2

Example 2 was a light-emitting module further including a light-transmissive member 3 that was disposed to cover the lens 2a in the light-emitting module 200 according to the second embodiment. The materials of the lens 2a and the light-transmissive member 3 were the same as those in Example 1, and the light-transmissive member 3 had the same configuration as in Example 1. In Example 2, the illuminance in the narrow-angle light distribution and illuminance in the ultra-wide-angle light distribution were rated as “Very good,” and the illuminance in the wide-angle light distribution was rated as “Good.” Each of FOV0®, FOV45°, and FOV90° was rated as “Good.” Therefore, in Example 2, all of the items satisfied the target values.

### Example 3

Example 3 evaluated optical characteristics of a light-emitting module further including the light-transmissive member 3 that was disposed to cover the lens 2b in the light-emitting module 300 according to the third embodiment. The materials of the lens 2b and the light-transmissive member 3 were the same as those in Example 1, and the light-transmissive member 3 had the same configuration as in Example 1. In Example 3, the illuminance of each of the narrow-angle light distribution, the wide-angle light distribution, and the ultra-wide-angle light distribution was rated as “Very good.” Each of FOV0®, FOV45°, and FOV90° was rated as “Good.” Therefore, in Example 3, all of the items satisfied the target values. In addition, from the result of the center illuminance, it was found that the light extraction efficiency was improved compared to the other examples because light refracted or reflected by the protrusion 61 can be utilized due to the first light-transmissive portion 20 including the annular protrusion 61.

### Reference Example 1

In Reference Example 1, the optical characteristics were evaluated for the light-emitting module, which was mainly different from the light-emitting module 100a according to the modified example of the first embodiment in that the through hole 23 was not provided in the first light-transmissive portion 20 and that the annular protrusion 24 was not included. In Reference Example 1, the illuminance in the narrow-angle light distribution was rated as “Very good,” and the illuminance in the wide-angle light distribution and the illuminance in the ultra-wide-angle light distribution were rated as “Good.” Each of FOV0® and the FOV45° was rated as “Good,” and FOV90° was rated as “Poor.” Therefore, in Reference Example 1, FOV90° did not satisfy the target value.

### Reference Example 2

Reference example 2 was a light-emitting module that was mainly different from the light-emitting module 100a according to the modified example of the first embodiment in that the through hole 23 was not provided in the first light-transmissive portion 20. In Reference Example 2, the illuminance in the narrow-angle light distribution was rated as “Very good,” and the illuminance in the wide-angle light distribution and the illuminance in the ultra-wide-angle light distribution were rated as “Poor.” Each of FOV0®, FOV45°, and FOV90° was rated as “Very good.” Therefore, in Reference Example 2, although FOV0°, FOV45°, and FOV90° were superior, the illuminance in the wide-angle light distribution and the illuminance in the ultra-wide-angle light distribution did not satisfy the target values.

From the results shown in Table 2, it was found that Example 1, Example 2, and Example 3 were superior to Reference Example 1 and Reference Example 2. In addition, it was found that Example 1 was slightly superior when compared to Example 2 and Example 3.

While preferred embodiments have been described in detail above, the present disclosure is not limited to the above-described embodiments, various modifications and substitutions can be made to the above-described embodiments without departing from the scope described in the claims.

The ordinal numbers, quantity, and the like used in the description of the embodiments are all exemplified to specifically describe the technique of the present disclosure, and the present disclosure is not limited to the numbers exemplified. In addition, the connection relationship between the components is exemplified to specifically describe the technique of the present disclosure, and the connection relationship for implementing the function of the present disclosure is not limited thereto.

The lens and the light-emitting module of the present disclosure are suitable for use in applications such as lighting, camera flashes, and in-vehicle headlights, because light distribution control can be performed. However, the lens and the light-emitting module of the present disclosure are not limited to these applications.

What is claimed is:

1. A lens comprising:
a first light-transmissive portion including a light incident surface and a light exiting surface located at a side opposite to the light incident surface, wherein:
the first light-transmissive portion has a through hole extending from the light incident surface to the light exiting surface, and
at least one of the light incident surface or the light exiting surface comprises:
an annular convex surface or an annular concave surface, and
at least one annular protrusion surrounding the through hole in a top view.

2. The lens according to claim 1, wherein:
each of the light incident surface and the light exiting surface comprises the annular convex surface that surrounds the through hole in a top view,
the annular protrusion is located at the light incident surface and surrounds the annular convex surface in a top view,
the annular protrusion comprises an inner lateral surface and an outer lateral surface, and
at least one of the inner lateral surface or the outer lateral surface is configured to refract or reflect light.

3. The lens according to claim 2, wherein:
the through hole comprises a first opening located at the light incident surface and a second opening located at the light exiting surface, and
the first opening is located between the annular protrusion and the second opening in a direction along a central axis of the through hole passing through a center of the first opening and a center of the second opening.

4. The lens according to claim 1, wherein:
the light exiting surface comprises the at least one annular protrusion, and
the at least one annular protrusion comprises:
an annular first protrusion configured to guide light to have a first light distribution angle, and
an annular second protrusion surrounding the annular first protrusion in a top view and configured to guide light to have a second light distribution angle greater than the first light distribution angle.

5. The lens according to claim 1, wherein:
the through hole comprises a first opening located at the light incident surface and a second opening located at the light exiting surface, the through hole being a tapered hole in which an area of the first opening is smaller than an area of the second opening.

6. The lens according to claim 1, wherein:
the first light-transmissive portion comprises a main body portion comprising a first main surface comprising the light incident surface and a second main surface located at a side opposite to the first main surface, and the annular protrusion disposed on the second main surface of the main body portion,
the annular protrusion comprises an inner lateral surface located on a through hole side, and an outer lateral surface located outward of the inner lateral surface, and
the first light-transmissive portion comprises, at the light exiting surface, an annular first concave surface surrounding the through hole, the annular first concave surface being composed of the inner lateral surface of the annular protrusion and the second main surface of the main body portion.

7. The lens according to claim 6, wherein:
an air layer is present between the outer lateral surface of the annular protrusion and the second main surface of the main body portion.

8. A light-emitting module, comprising:
a light source comprising:
one or more first light-emitting units located in a central region of the light source in a top view, and
one or more second light-emitting units located in an outer peripheral region located on an outer periphery of the central region in a top view, wherein:
the one or more first light-emitting units and the one or more second light-emitting units are configured to be driven individually or in groups; and
the lens according to claim 1, the lens being disposed above the light source, wherein:
the light source is disposed such that the one or more first light-emitting units overlap the through hole in a top view,
light emitted from the one or more first light-emitting units is irradiated through the through hole at a first full width at half maximum angle, and light emitted from the one or more second light-emitting units is irradiated through the annular protrusion at a second full width at half maximum angle, and
the first full width at half maximum angle is smaller than the second full width at half maximum angle.

9. The light-emitting module according to claim 8, wherein:
among light emitted from the second light-emitting unit, light irradiated through the annular protrusion travels in a direction toward a central axis of the first light-transmissive portion and is irradiated onto an irradiation surface.

10. The light-emitting module according to claim 8, wherein:
the one or more second light-emitting units comprise a plurality of light-emitting units configured to be driven individually or in groups.

11. The light-emitting module according to claim 8, wherein:
in a top view:
each of the light incident surface and the light exiting surface comprises the annular convex surface surrounding the through hole,
the annular protrusion surrounds the annular convex surface and is located on the light incident surface,
the light source comprises a rectangular light-emitting region, and
a corner portion of the light-emitting region overlaps the annular protrusion.

12. The light-emitting module according to claim 8, further comprising:
a light-transmissive member, wherein
the lens comprises a first support portion supporting the first light-transmissive portion,
the light-transmissive member comprises:
a second light-transmissive portion facing the light exiting surface of the lens, and
a second support portion supporting the second light-transmissive portion are further provided, and
the first support portion is fixed to the second support portion.

13. The light-emitting module according to claim 8, wherein:
the light exiting surface comprises the at least one annular protrusion,
the at least one annular protrusion comprises:
an annular first protrusion configured to guide light to have a first light distribution angle, and
an annular second protrusion surrounding the annular first protrusion in a top view and configured to guide light to have a second light distribution angle greater than the first light distribution angle,
light emitted from the one or more first light-emitting units and refracted or reflected by the first protrusion comprises a first light beam,
light emitted from the one or more second light-emitting units and refracted or reflected by the second protrusion comprises a second light beam, and
an angle formed between the second light beam and a central axis of the first light-transmissive portion is greater than an angle formed between the first light beam and the central axis of the first light-transmissive portion.

14. The light-emitting module according to claim 8, wherein:
the first light-transmissive portion comprises a main body portion comprising a first main surface comprising the light incident surface and a second main surface located at a side opposite to the first main surface, and the annular protrusion disposed on the second main surface of the main body portion,
the annular protrusion comprises an inner lateral surface located on a through hole side, and an outer lateral surface located outward of the inner lateral surface,
the first light-transmissive portion comprises, at the light exiting surface, an annular first concave surface surrounding the through hole, the annular first concave surface being composed of the inner lateral surface of the annular protrusion and the second main surface of the main body portion, and
light emitted from the one or more first light-emitting units comprises light irradiated through the through hole and light refracted or reflected by the outer lateral surface of the annular protrusion.

15. The light-emitting module according to claim 8, wherein:
the first light-transmissive portion comprises a main body portion comprising a first main surface comprising the light incident surface and a second main surface located at a side opposite to the first main surface, and the annular protrusion disposed on the second main surface of the main body portion,
the annular protrusion comprises an inner lateral surface located on a through hole side, and an outer lateral surface located outward of the inner lateral surface,
the first light-transmissive portion comprises, at the light exiting surface, an annular first concave surface surrounding the through hole, the annular first concave surface being composed of the inner lateral surface of the annular protrusion and the second main surface of the main body portion, and
at least a part of light emitted from the one or more second light-emitting units is diffused by the annular first concave surface.

16. The light-emitting module according to claim 8, wherein:
the first light-transmissive portion comprises a main body portion comprising a first main surface comprising the light incident surface and a second main surface located at a side opposite to the first main surface, and the annular protrusion disposed on the second main surface of the main body portion,
the annular protrusion comprises an inner lateral surface located on a through hole side, and an outer lateral surface located outward of the inner lateral surface,
the first light-transmissive portion comprises, at the light exiting surface, an annular first concave surface surrounding the through hole, the annular first concave surface being composed of the inner lateral surface of the annular protrusion and the second main surface of the main body portion, and
the light incident surface of the first light-transmissive portion comprises an annular second concave surface at a position overlapping the one or more second light-emitting units in a top view.
